(19) United States
(12) Patent Application Publication
(10) Pub. No.: US 2024/0381569 A1
(43) Pub. Date: Nov. 14, 2024

(54) COOLER FOR COOLING POWER ELECTRONICS

(71) Applicant: Robert Bosch GmbH, Stuttgart (DE)

(72) Inventors: Maik Paehrisch, Reutlingen (DE); Max Florian Beck, Vaihingen An Der Enz (DE)

(21) Appl. No.: 18/691,248

(22) PCT Filed: Aug. 11, 2022
(86) PCT No.: PCT/EP2022/072565

§ 371 Date: Mar. 12, 2024

(30) Foreign Application Priority Data
Oct. 1, 2021 (DE) 10 2021 211 059.2

(51) Int. Cl. H05K 7/20

(52) U.S. Cl. CPC H05K 7/20263; H05K 7/20927

(57) ABSTRACT

The invention relates to a housing (2) for installing the power electronics (101) and a cooling rib assembly (7) with a plurality of ribs (9) in a cooling channel (6) of the housing (2), wherein fluid can flow through the cooling rib assembly (7) along a longitudinal axis (30), wherein the cooling rib assembly (7) comprises at least one strong cooling region (20) with a first flow resistance for the fluid and at least one weak cooling region (21) with a second flow resistance for the fluid, wherein the first flow resistance is greater than the second flow resistance.

### BACKGROUND

The present invention relates to a cooler for cooling power electronics. The invention further discloses an assembly comprising the cooler along with the power electronics.

Power semiconductors in power electronics carry high electrical currents. Together with switching losses, the resulting conductive losses are the cause of a high heat loss, which has to be dissipated over a relatively small area. The maximum permissible semiconductor temperature is thereby critical to failure, for which reason minimizing the thermal resistance between the semiconductor and coolant is of central importance. For efficient cooling, the power electronics addressed herein are applied to coolers, through which fluid flows. Conventionally, rib assemblies, through which the fluid flows, are located in said coolers.

### SUMMARY

The cooler according to the invention is in particular designed to cool power electronics. These power electronics comprise one or more power semiconductors, which are conventionally arranged in a substrate. The cooler comprises a housing that is designed to accommodate the power electronics. Preferably, the housing is plate-shaped with, e.g., two plates defining a coolant chamber between them through which cooling fluid can flow. The cooling channel forms a cavity. Located in said cavity is a cooling rib assembly comprising a plurality of ribs. The cooling channel and the cooling rib assembly are designed to enable the passage of a cooling fluid. Cooling is in particular performed using a fluid in the liquid aggregate state. The cooling rib assembly is designed so that the fluid can flow through it along a longitudinal axis. A transverse axis is defined perpendicular to the longitudinal axis and thus also perpendicular to the flow direction. A vertical axis is defined as being perpendicular to the transverse axis and perpendicular to the longitudinal axis. In particular, the cooling rib assembly extends much further in the direction of the longitudinal axis and in the direction of the transverse axis than in the direction of the vertical axis. The power electronics are positioned along the vertical axis above or below the cooling rib assembly. A plurality of heat sources of the power electronics, in particular a plurality of the power semiconductors, can be positioned along the longitudinal axis and in part also along the transverse axis. Within the cooling channel of the housing or within the cooling rib assembly, a pressure drop results along the flow direction due to the resistance of the fluid flowing through the cooling rib assembly. The higher the heat transfer coefficient through the cooling rib assembly, the higher the pressure drop will generally be. In the cooling system, the maximum allowable pressure drop due to the pump for the fluid is limited. It is therefore necessary to also limit the pressure drop in the entire cooler, whereby under certain circumstances the maximum possible heat transfer coefficient cannot be exploited. The cooler according to the invention has the advantage that the pressure drop in the cooler can be reduced. This is achieved by the cooling rib assembly comprising at least one strong cooling region with a first flow resistance for the fluid and at least one weak cooling region with a second flow resistance for the fluid. The cooling rib assembly in the strong cooling region and in the weak cooling region is designed such that the first flow resistance is higher than the second flow resistance. Particularly preferably, the first flow resistance is at least 10% higher than the second flow resistance. The at least one weak cooling region with the second flow resistance can be intentionally positioned within the cooler at locations where no or little cooling is required. In particular, the strong cooling regions are positioned as close as possible to the power semiconductors, whereas the weak cooling regions are positioned more at the edges of the cooling rib assembly and/or between two power semiconductors. As a result, the fluid flowing through is only subjected to a correspondingly high flow resistance in intentionally selected strong cooling regions required for cooling, which also leads to a correspondingly high heat transfer coefficient. In regions where little or no cooling is necessary, i.e., in the weak cooling regions, the flow resistance is reduced as much as possible so that the lowest possible flow resistance, or rather the flow resistance adjusted to thermal requirements, is achieved with respect to the cooling rib assembly in general.

As described, the housing is preferably formed from two plates that define the cooling channel between them. The two plates are connected to each other, in particular via a brazing layer, and thereby form the cooling channel for receiving the cooling rib assembly. An inlet and an outlet for the fluid preferably lead into this cooling channel.

The cooling rib assembly preferably comprises at least two, further preferably at least three, more preferably at least four, of the described weak cooling regions. These weak cooling regions can be the same or can be designed differently. The weak cooling regions are distributed and spaced apart along the longitudinal axis such that a strong cooling region is preferably located between the weak cooling regions. In addition to these weak cooling regions arranged one behind another along the longitudinal axis, one or more weak cooling regions can also be arranged next to one another along the transverse axis.

It is preferably provided that the weak cooling regions take on a first area and the strong cooling regions take on a second area of the cooling rib assembly in total, whereby the areas are each defined in the plane spanned by the longitudinal axis and the transverse axis. Preferably, the first area takes on at least 10%, in particular at least 20%, of the total area of the cooling rib assembly and at the same time the second area takes on at least 10%, in particular at least 20%, of the total area of the cooling rib assembly.

In at least one strong cooling region, preferably the ribs of the cooling rib assembly, measured transversely to the longitudinal axis, are closer than the ribs in at least one adjacent weak cooling region. The distance between two ribs measured parallel to the transverse axis is thus smaller in the strong cooling region than in the weak cooling region, resulting in a greater flow resistance in the strong cooling region than in the weak cooling region. Additionally or alternatively, it is possible that no ribs are designed at all in at least one weak cooling region.

Furthermore, it is preferably provided that the cooling rib assembly is manufactured by forming a sheet metal into a turbulence plate. This turbulence plate has in particular a plurality of rows of ribs. The individual row of ribs extends perpendicular to the longitudinal axis along the transverse axis. The individual row of ribs has a plurality of ribs. In particular, the row of ribs has a wave shape. This wave shape connects two adjacent ribs to each other via a mountain or valley portion of the wave shape. The mountain or valley portion of the wave shape or the row of ribs extends in particular substantially in a plane spanned by the longitudinal axis and the transverse axis.

In the turbulence plate, at least one of the weak cooling regions is preferably formed by a free space that is cut out. This free space is in particular punched out or otherwise cut out. In particular, the turbulence plate is initially manufactured without any free space and after manufacture of the turbulence plate, the free spaces are cut out at the desired locations. This results in regions without ribs at the free spaces that form as low a flow resistance as possible in the weak cooling region.

The at least one weak cooling region can be used to direct the flow, for example to direct the flow with a directional component parallel to the transverse axis and/or to focus the flow of the fluid on a region to be cooled more strongly. In order to achieve such a flow direction, it is particularly provided that the free space in the turbulence plate described above is tapered. In particular, the free space tapers in the flow direction, so that the fluid can be intentionally directed and channeled.

The individual ribs of the cooling rib assembly are, preferably at least in the strong cooling region, adjusted at a first setting angle to the longitudinal axis. In particular, the ribs are adjusted so as to increase the flow resistance and consequently also increase the heat transfer coefficient compared to a non-adjusted state.

It is preferably provided that the ribs in the strong cooling region are adjusted at a setting angle to the longitudinal axis and the ribs in at least one adjacent weak cooling region are adjusted at a lower angle or are not set not at all, i.e., parallel to the longitudinal axis.

The individual strong cooling region preferably comprises a plurality of rows of ribs arranged one behind the other. The rows of ribs extend along the transverse axis as described in the context of the turbulence plate and are directly adjacent to each other along the longitudinal axis. Preferably, the ribs in adjacent rows of ribs are adjusted at different setting directions to the longitudinal axis, such that, for example, the ribs of the one row are adjusted to 10° and the ribs of the next row to −10° to the longitudinal axis. This alternating adjustment of the ribs deliberately increases the flow resistance in order to achieve as high a heat transfer coefficient as possible in the strong cooling region.

It is preferably provided that the ribs have a first length in at least one strong cooling region and the ribs have a second length in at least one adjacent weak cooling region. The length of the individual rib is in this case measured parallel to the longitudinal axis. The second length is preferably greater than the first length. The ribs in the weak cooling region are thereby designed longer than the ribs in the strong cooling region and preferably without the setting angle. This is of particular interest in combination with the changing setting direction of the individual row of ribs described above, as the relatively long ribs form a relatively long section in the weak cooling region without changing the setting angle and thus provide reduced flow resistance.

The various embodiments described herein for intentionally changing the flow resistance in the weak cooling region and in the strong cooling region can also be combined with one another within a cooling rib assembly. A weak cooling region in the cooling rib assembly can, e.g., be formed by a free space that is cut out, and another weak cooling region in the same cooling rib assembly can be achieved by changing the length of the ribs or changing the setting angle.

The invention further comprises an assembly. The assembly in turn combines the described cooler and the associated power electronics comprising at least one power semiconductor. As described, the power electronics are in this case arranged on the cooler. In an imaginary projection of the power semiconductors along the vertical axis onto the plane of the cooling rib assembly, the positioning of weak cooling regions and strong cooling regions relative to the power semiconductors can be considered. It is particularly provided that only strong cooling regions are formed directly under the power semiconductors and the weak cooling regions are located between the power semiconductors.

### BRIEF DESCRIPTION OF THE DRAWINGS

An exemplary embodiment of the invention is described in detail hereinafter with reference to the accompanying drawings. The drawings include:

FIG. 1 a schematic cross-sectional view of an assembly according to the invention with a cooler according to the invention according to an exemplary embodiment,

FIG. 2 a schematic plan view of the cooler according to the invention according to the exemplary embodiment,

FIG. 3 a plan view of a cooling rib assembly of the cooler according to the invention according to the exemplary embodiment,

FIG. 4 a first detail view of the cooling rib assembly of FIG. 3, and

FIG. 5 a second detail view of the cooling rib assembly of FIG. 3.

### DETAILED DESCRIPTION

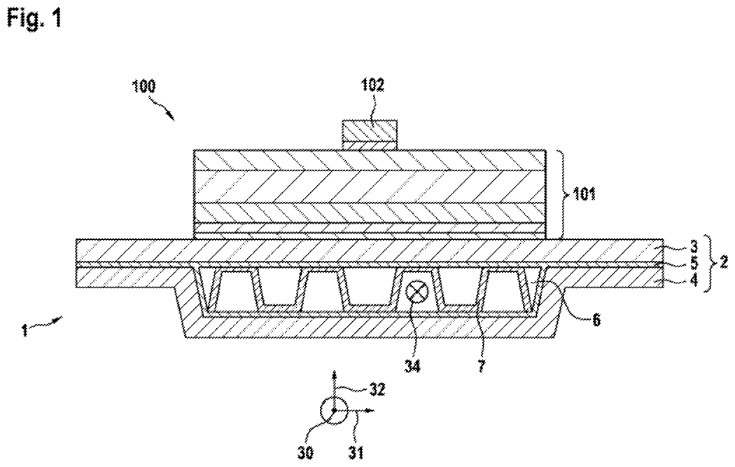

An assembly 100 comprising a cooler 1 will be described in detail hereinafter with reference to FIGS. 1 to 5. According to the schematic sectional view in FIG. 1, the assembly 100 comprises power electronics 101 located on the cooler 1. The power electronics 101 comprise one or more power semiconductors 102, which are considered as primary heat sources herein.

FIG. 1 further shows that the cooler 1 is plate-shaped with two interconnected cooling plates 3, 4 (forming a housing 2) arranged in parallel, between which is a cooling channel 6. The two cooling plates 3, 4 are interconnected via a soldering layer 5.

A cooling rib assembly 7 is located in the cooling channel 6, which can also be connected to the housing 2 via the soldering layer 5.

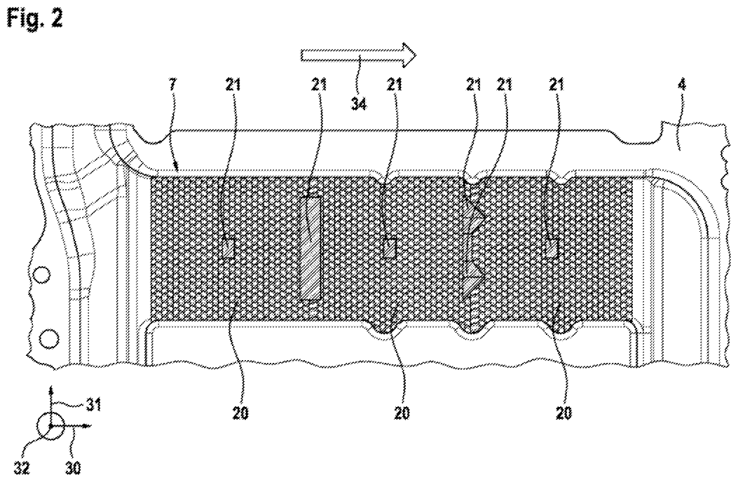

FIG. 2 shows a plan view of the cooler 1. The upper cooling plate 3 is hidden for the sake of clarity so that the lower cooling plate 4 with the cooling rib assembly 7 received therein can be seen.

As shown in FIGS. 1 to 5, a longitudinal axis 30, a transverse axis 31, and a vertical axis 32 are defined on the cooler 1. The three axes 30, 31, and 32 are each perpendicular to one another.

The housing 2 is designed for the passage of a cooling fluid along a flow direction 34. The flow direction 34 extending parallel to the longitudinal axis 30 is the main flow direction from the housing-side inlet to the housing-side outlet of the fluid. Within the cooling rib assembly 7, the fluid can also flow with a directional component parallel to the transverse axis 31.

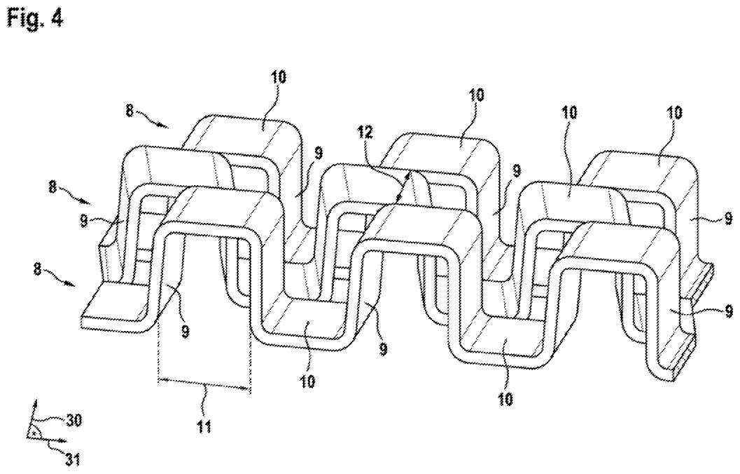

In the exemplary embodiment shown, the cooling rib assembly 7 is formed by a shaped sheet metal and can also be referred to as a turbulence plate. The cooling rib assembly 7 is composed of a plurality of rows of ribs 8. Each row of ribs 8 extends along the transverse axis 31. The plurality of rows of ribs 8 are arranged directly adjacent to one another along the longitudinal axis 30. FIG. 4 shows in a detail view 3 these rows of ribs 8. The individual row of ribs 8 is in this case wave-shaped, whereby two adjacent ribs 9 are interconnected by a mountain or valley portion 10 of the wave shape. Parallel to the transverse axis 31, there is in this case a distance 11 between two adjacent ribs 9. The individual rib 9 extends parallel to the longitudinal axis 30 over a first length 12.

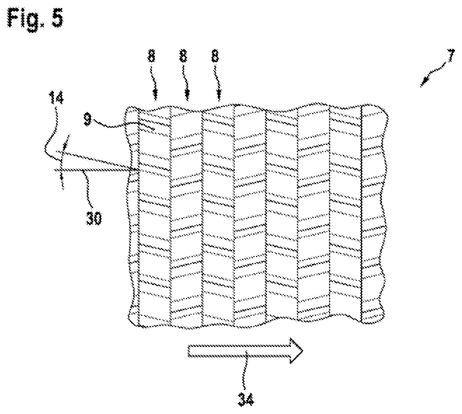

The detail view in FIG. 5 shows that the ribs 9 can be inclined with a setting angle 14 opposite the longitudinal axis 30.

FIG. 2 purely schematically illustrates the positioning and design of weak cooling regions 21. These weak cooling regions 21 of the cooling rib assembly 7 are surrounded by strong cooling regions 20 of the cooling rib assembly 7. Along the longitudinal axis 3, i.e., along the flow direction 34, a plurality of these weak cooling regions 31 are integrated in the cooling rib assembly 7 in various shapes and sizes. In the weak cooling regions 31, the fluid flowing through is subjected to less flow resistance than in the strong cooling regions 20. As a result, a higher heat transfer coefficient is possible in the strong cooling regions 20. Accordingly, strong cooling regions 20 are preferably located below the power semiconductors 102, whereas the weak cooling regions 21 are arranged between the power semiconductors 102.

FIG. 2 schematically illustrates two triangular, weak cooling regions 21, which are designed to taper along the flow direction 35 in order to direct or channel the fluid accordingly.

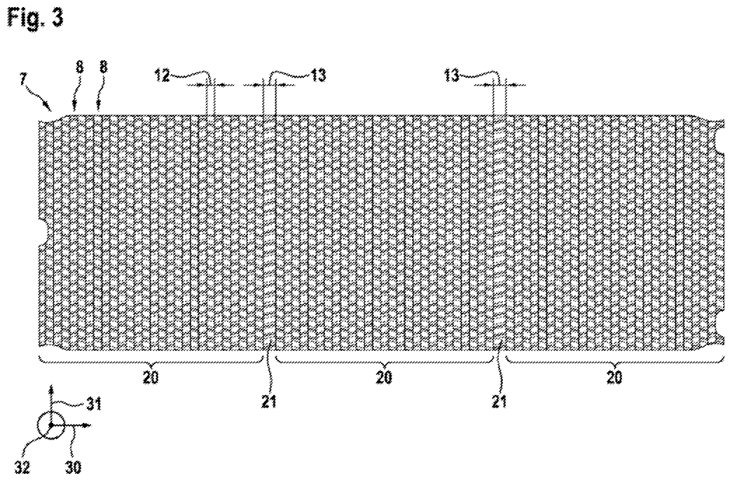

As previously described in the introductory section, a free space in the cooling rib assembly 7 can be cut out in order to form the weak cooling regions 21. Additionally or alternatively, it is also possible to form the length of the ribs 9 longer in the weak cooling region 21 than in the strong cooling regions 20. By way of example, FIG. 3 shows two weak cooling regions 21 that extend over the entire width (along the transverse axis 31) of the cooling rib assembly 7. In these two weak cooling regions 21 according to FIG. 3, the ribs 9 are designed with a second length 13, which is longer than a first length 12 of the ribs 9 in the three strong cooling regions 20.

The setting angle 14 was previously explained with reference to FIGS. 4 and 5. This setting angle 14 can preferably be less than or equal to zero in the weak cooling regions 21 to produce less flow resistance in the weak cooling regions 21 than in the surrounding strong cooling regions 20.

1. A cooler (1) for cooling power electronics (101), the cooler (1) comprising:
a housing (2) for installing the power electronics (101)
and a cooling rib assembly (7) with a plurality of ribs (9) in a cooling channel (6) of the housing (2),
wherein fluid can flow through the cooling rib assembly (7) along a longitudinal axis (30),
wherein the cooling rib assembly (7) comprises at least one strong cooling region (20) with a first flow resistance for the fluid and at least one weak cooling region (21) with a second flow resistance for the fluid, said first flow resistance being greater than the second flow resistance.

2. The cooler according to claim 1, wherein the cooling rib assembly (7) comprises at least two weak cooling regions (21) distributed and spaced apart along the longitudinal axis.

3. The cooler according to claim 1, wherein, in at least one strong cooling region (20), the ribs (9) of the cooling rib assembly (7) when measured transversely to the longitudinal axis (30) are closer together than the ribs (9) in at least one adjacent weak cooling region (21).

4. The cooler according to claim 1, wherein no ribs (9) are formed in at least one weak cooling region (21).

5. The cooler according to claim 1, wherein the cooling rib assembly (7) is manufactured by forming sheet metal into a turbulence plate, and wherein at least one weak cooling region (21) being a free space in the turbulence plate that is cut out.

6. The cooler according to claim 1, wherein at least one weak cooling region (21) is tapered for flow direction.

7. The cooler according to claim 1, wherein, in at least one strong cooling region (20), the ribs (9) are adjusted at a setting angle to the longitudinal axis, and the ribs (9) are adjusted less in at least one adjacent weak cooling region (21).

8. The cooler according to claim 1, wherein at least one strong cooling region (20) comprises a plurality of rows of ribs (8), each extending transversely to the longitudinal axis (30) and adjoining one another directly along the longitudinal axis (30), wherein the ribs (9) in a respective row of ribs (8) are adjusted at a same setting direction opposite to the longitudinal axis (30), and wherein the ribs (9) are adjusted opposite to two adjacent rows of ribs (8).

9. The cooler according to claim 1, wherein, in at least one strong cooling region (20), the ribs (9) have a first length (12) measured parallel to the longitudinal axis (30), and the ribs (9) in at least one adjacent weak cooling region (21) have a second length (13) measured parallel to the longitudinal axis (30), wherein the second length (13) is greater than the first length (12).

10. An assembly (100) comprising a cooler (1) according to claim 1 and power electronics (101) having a plurality of power semiconductors (102) arranged on the housing (2).

11. The cooler according to claim 2, wherein the cooling rib assembly (7) comprises at least three weak cooling regions (21).

12. The cooler according to claim 2, wherein the cooling rib assembly (7) comprises at least four weak cooling regions (21).

13. The cooler according to claim 5, wherein the at least one weak cooling region (21) is a free space in the turbulence plate that is stamped out.

14. The cooler according to claim 6, wherein the ribs (9) are adjusted less in at least one adjacent weak cooling region (21) parallel to the longitudinal axis (30).
